(19) United States
(12) Patent Application Publication
(10) Pub. No.: US 2016/0273128 A1
(43) Pub. Date: Sep. 22, 2016

(54) EPITAXIAL WAFER GROWTH APPARATUS

(71) Applicant: LG SILTRON INC., Gyeongsangbuk-do (KR)

(72) Inventor: Yu-Jin Kang, Gyeongsangbuk-do (KR)

(21) Appl. No.: 15/037,323

(22) PCT Filed: Sep. 3, 2014
(86) PCT No.: PCT/KR2014/008282

§ 371 Date: May 17, 2016

(30) Foreign Application Priority Data
Nov. 25, 2013 (KR) 10-2013-0143993

(51) Int. Cl. C30B 25/10; C23C 16/455; C30B 29/06; C30B 25/08; C30B 25/12

(52) U.S. Cl. CPC C30B 25/10; C30B 25/08; C30B 25/12; C30B 29/06; C23C 16/455

(57) ABSTRACT

An epitaxial wafer growth apparatus for growing an epitaxial layer on a wafer using a process gas flow is disclosed. The apparatus comprises a reaction chamber; upper and lower liners surrounding the reaction chamber; a susceptor in the reaction chamber, the susceptor configured to support the wafer thereon; a preheat ring seated on a top face of the lower liner, the preheat ring being coplanar with the susceptor, and the preheat ring being spaced from the the susceptor; and at least one protrusion extending downwards from the preheat ring, wherein the protrusion has a circumferential contact face with a circumferential side face of the lower liner, wherein the protrusion is configured to fix the preheat ring to the lower liner to keep a uniform space between the preheat ring and susceptor along the preheat ring.

### CROSS-REFERENCE TO RELATED APPLICATIONS

The present application is a national phase application of International Application PCT/KR2014/008282, with an international filing date of Sep. 3, 2014, which claims the priority benefit of Korea Patent Application No. 10-2013-0143993 filed on Nov. 25, 2013, the entire contents of which are incorporated herein by reference for all purposes as if fully set forth herein.

### BACKGROUND

1. Field of the Present Disclosure

The present disclosure relates to an epitaxial growth apparatus, and, more particularly, to an epitaxial growth apparatus for growing a silicon mono-crystalline epitaxial thin layer on a wafer.

2. Discussion of the Related Art

An epitaxial silicon wafer refers to a silicon mono-crystalline epitaxial thin layer grown on a mirror-like finished silicon wafer. Regarding a formation of the epitaxial silicon wafer, a mirror-like finished silicon wafer is mounted on a susceptor in an epitaxial reactor, and, then, a source gas is supplied from one side end to the other side end of the reactor. Thus, the gas reacts with the wafer to form a grown epitaxial layer on a surface of the wafer.

FIG. 1 illustrates a cross-sectional view of a conventional epitaxial reactor. Referring to FIG. 1, a lower liner 102 is disposed on an outer peripheral face of a reactor vessel 101, and a susceptor 105 is disposed within the reactor vessel 101 and adjacent to the lower liner 102 in a symmetrical manner. The susceptor 105 allows a wafer W to be mounted thereon. For this, the susceptor 105 is supported by a susceptor support 106. At one side end of the reactor vessel 101, a gas inlet 103 is disposed to receive a source gas from a gas supply, which, in turn, is supplied onto a surface of the wafer W on the susceptor 105. At the other side end of the reactor vessel 101, a gas outlet 104 is disposed to receive the gas via the wafer and discharge the gas outside of the vessel.

On an inner peripheral face of the lower liner 102, a preheat ring 108 is disposed to enable uniform thermal transfer toward the wafer. The preheat ring 108 is disposed to be coplanar with the susceptor 105 and to surround the susceptor 105.

The preheat ring 108 is implemented as a plate ring seated on the lower liner 102. Thus, the preheat ring 108 may be deformed and/or displaced due to a thermal expansion from a high temperature and/or a vibration during an epitaxial deposition process.

FIG. 2 illustrates a top view of a state where there occurs a contact between the susceptor and preheat ring. Referring to FIG. 2, When the preheat ring 108 is deformed or displaced to partially contact the susceptor 105, the gas flow on and along the wafer on susceptor 105 may be influenced. Thus, this may lead to a deposited non-uniform thickness of the water, especially at an edge thereof.

Further, when the preheat ring 108 is deformed or displaced in a contacted state with the lower liner 102, there may occur a friction between the lower liner 102 and ring 109. This may lead to particles being generated. Such particles may contaminate the reaction gas in the reactor vessel 101 to deteriorate a quality of a resulting epitaxial wafer.

Furthermore, the friction between the preheat ring 108 and susceptor 105 may peel off a silicon carbide (SiC) coating from the susceptor 105, and/or a metal covered with the coating may be removed from the susceptor 105 to form metal particles in the reaction vessel. Those may further contaminate the reaction gas in the reactor vessel 101. This may deteriorate a quality of a resulting epitaxial wafer and thus lower a yield of the epitaxial wafer.

This “Discussion of the Related Art” section is provided for background information only. The statements in this “Discussion of the Related Art” are not an admission that the subject matter disclosed in this “Discussion of the Related Art” section constitutes prior art to the present disclosure, and no part of this “Discussion of the Related Art” section may be used as an admission that any part of this application, including this “Discussion of the Related Art” section, constitutes prior art to the present disclosure.

### SUMMARY

From considerations of the above, the present disclosure provides means for fixing the preheat ring to the lower liner and thus allowing an uniform spacing between the preheat ring and the susceptor during a hot epitaxial deposition process.

The present disclosure provides mean for allowing a reduced contact area between the preheat ring and lower liner while the uniform spacing between the preheat ring and the susceptor is kept.

In an aspect of the present disclosure, there is provided an epitaxial wafer growth apparatus for growing an epitaxial layer on a wafer using a process gas flow, the apparatus comprising: a reaction chamber in which the process gas flow occurs; upper and lower liners, each liner surrounding a side face of the reaction chamber; a susceptor concentrically disposed in and with the reaction chamber, the susceptor configured to support the wafer thereon; a preheat ring seated on a top face of the lower liner, the preheat ring being coplanar with the susceptor, and the preheat ring being spaced from the susceptor; and at least one protrusion extending downwards from the preheat ring, wherein the protrusion has a circumferential contact face with a circumferential side face of the lower liner, wherein the protrusion is configured to fix the preheat ring to the lower liner to keep a uniform space between the preheat ring and susceptor along the preheat ring.

The epitaxial growth apparatus of the present disclosure includes the fixing member configured to fix the preheat ring to the lower liner, and, thus, to suppress the horizontal deformation and/or displacement of the preheat ring. This may lead to the uniform gas flow rate on and along wafer surface, and, hence, the uniform epitaxial layer thickness especially in the edge thereof. This may improve better smoothness of the resulting wafer, and, thus, a better yield of a semiconductor device.

Further, in accordance with the present disclosure, the particles creations resulting from the friction between the preheat ring and lower liner may be reduced, to suppress the contaminations of the resulting grown epitaxial wafer.

Furthermore, in accordance with the present disclosure, there may be suppressed a contact between the preheat ring and susceptor such that particles creations resulting from the peeled off coating of the susceptor due to the friction between the preheat ring and susceptor are minimized. This may lead to a uniform quality of the resulting epitaxial wafer.

### BRIEF DESCRIPTIONS OF THE DRAWINGS

The accompanying drawings, which are included to provide a further understanding of the present disclosure and are incorporated in and constitute a part of this specification, illustrate embodiments of the present disclosure and together with the description, and serve to explain the principles of the present disclosure. In the drawings:

FIG. 1 illustrates a cross-sectional view of a conventional epitaxial reactor.

FIG. 2 illustrates a top view of a state where there occurs a contact between the susceptor and preheat ring.

FIG. 3 illustrates a cross-sectional view of an epitaxial growth apparatus 200 in accordance with one embodiment of the present disclosure.

FIG. 4 illustrates a cross-sectional view of a preheat ring in an accordance with one embodiment of the present disclosure.

FIG. 5 illustrate a bottom view of a preheat ring in accordance with one embodiment of the present disclosure.

FIG. 6 illustrates a cross-sectional view of a preheat ring in accordance with another embodiment of the present disclosure.

FIG. 7 illustrates a top view of a preheat ring and susceptor in accordance with the present disclosure.

FIG. 8 illustrates a comparison in LLS (Localized Light Scatters) defects between resulting wafers respectively in cases of presence and absence of a contact between a susceptor and a preheat ring during a wafer epitaxial process.

FIG. 9 illustrates epitaxial layer thickness variations over a radial direction, respectively for resulting wafers respectively in cases of presence and absence of a contact between a susceptor and a preheat ring during a wafer epitaxial process.

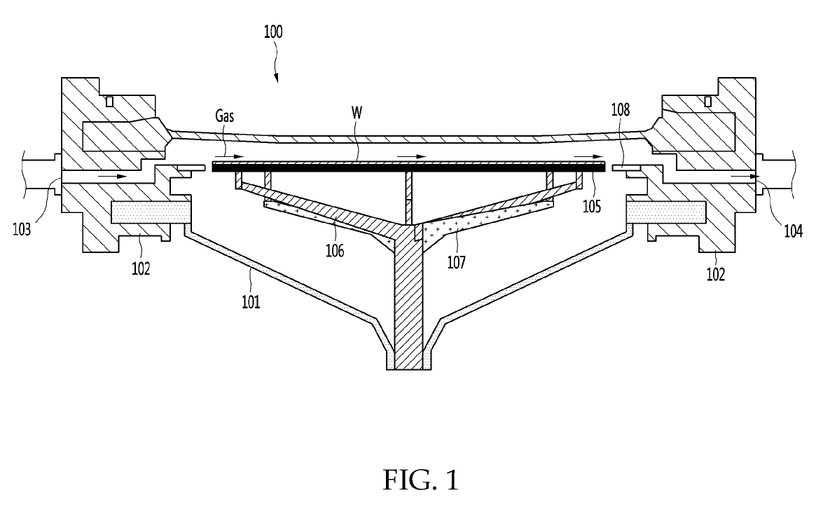

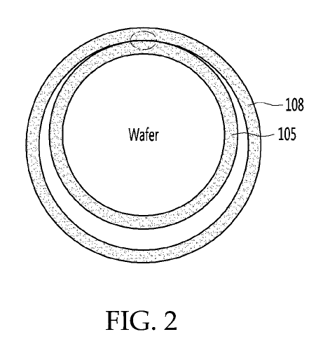

### DETAILED DESCRIPTION

Examples of various embodiments are illustrated in the accompanying drawings and described further below. It will be understood that the description herein is not intended to limit the claims to the specific embodiments described. On the contrary, it is intended to cover alternatives, modifications, and equivalents as may be included within the spirit and scope of the present disclosure as defined by the appended claims.

Example embodiments will be described in more detail with reference to the accompanying drawings. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art.

It will be understood that, although the terms “first”, “second”, “third”, and so on may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

It will be understood that when an element or layer is referred to as being “connected to”, or “coupled to” another element or layer, it can be directly on, connected to, or coupled to the other element or layer, or one or more intervening elements or layers may be present. In addition, it will also be understood that when an element or layer is referred to as being “between” two elements or layers, it can be the only element or layer between the two elements or layers, or one or more intervening elements or layers may also be present.

The terminology used herein is for the purpose of describing particular embodiments only and is not intended to be limiting of the present disclosure. As used herein, the singular forms “a” and “an” are intended to include the plural forms as well, unless the context clearly indicates otherwise. It will be further understood that the terms “comprises”, “comprising”, “includes”, and “including” when used in this specification, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of the associated listed items. Expression such as “at least one of” when preceding a list of elements may modify the entire list of elements and may not modify the individual elements of the list.

Spatially relative terms, such as “beneath,” “below,” “lower,” “under,” “above,” “upper,” and the like, may be used herein for ease of explanation to describe one element or feature's relationship to another element s or feature s as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented for example, rotated 90 degrees or at other orientations, and the spatially relative descriptors used herein should be interpreted accordingly.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

In the following description, numerous specific details are set forth in order to provide a thorough understanding of the present disclosure. The present disclosure may be practiced without some or all of these specific details. In other instances, well-known process structures and/or processes have not been described in detail in order not to unnecessarily obscure the present disclosure.

Further, all numbers expressing dimensions, physical characteristics, and so forth, used in the specification and claims are to be understood as being modified in all instances by the term “about”. Accordingly, unless indicated to the contrary, the numerical values set forth in the following specification and claims can vary depending upon the desired properties sought to be obtained by the practice of the present disclosure. Moreover, all ranges disclosed herein are to be understood to encompass any and all subranges subsumed therein. For example, a stated range of “1 to 10” should be considered to include any and all subranges between (and inclusive of) the minimum value of 1 and the maximum value of 10; that is, all subranges beginning with a minimum value of 1 or more and ending with a maximum value of 10 or less, e.g., 1 to 6.3, or 5.5 to 10, or 2.7 to 6.1.

As used herein, the term “substantially,” “about,” and similar terms are used as terms of approximation and not as terms of degree, and are intended to account for the inherent deviations in measured or calculated values that would be recognized by those of ordinary skill in the art. Further, the use of “may” when describing embodiments of the present disclosure refers to “one or more embodiments of the present disclosure.”

Hereinafter, various embodiments of the present disclosure will be described in details with reference to attached drawings.

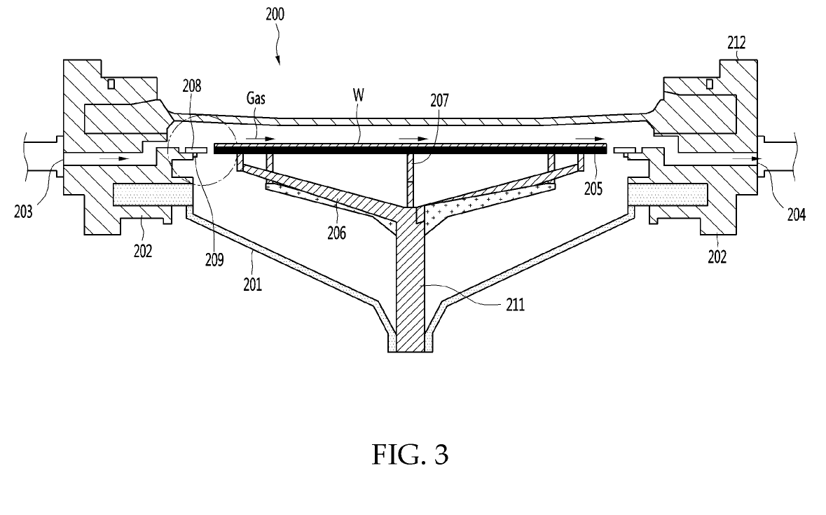

FIG. 3 illustrates a cross-sectional view of an epitaxial growth apparatus 200 in accordance with one embodiment of the present disclosure. Referring to FIG. 3, the epitaxial growth apparatus 200 may be implemented in a single wafer type where an epitaxial growth process for a single wafer W is conducted therein. The epitaxial growth apparatus 200 may include a reaction chamber 201, gas supply 203, gas outlet 204, susceptor 205, susceptor support 206, susceptor support pin 207, lower liner 202, upper liner 212, preheat ring 208, and main shaft 211.

The reaction chamber 201 may be made of quartz. Along an outer peripheral face of the reaction chamber 201, the lower liner 202 may be disposed. Above the lower liner 202, the upper liner 212 may be disposed to be spaced from the lower liner 202. Thus, there may be generated a certain channel between the upper liner 212 and lower liner 202 for a gas flow. One side portion of the channel may define the gas inlet 203, while the other side portion of the cannel opposite the one side portion may define the gas outlet 204. Through the gas inlet 203, a source gas may be introduced into the reaction chamber 201, and may flow along the wafer surface and may be discharged through the gas outlet 204 outside of the chamber.

The susceptor 205 may be implemented as a circular flat support plate made of a silicon carbide coated with a carbon graphite. The susceptor 205 may be concentrically disposed with an inner outer circumference of the reaction chamber 201. On the susceptor 205, the wafer W may be seated for forming a thin layer thereon.

The susceptor 205 may be supported by the main shaft 211. To be specific, the main shaft 211 may be branched in a given angle into a plurality of susceptor supports 206. Each support 206 may support the susceptor 205. In this connection, each susceptor support 206 may have each support pin 207 disposed at a free end thereof, which may support an outer periphery of the susceptor 205. In this way, the susceptor 205 may be supported evenly and horizontally.

The preheat ring 208 may be coplanar with the susceptor 205. The preheat ring 208 may be implemented as a plate-shaped ring seated on a horizontal outer peripheral face of the lower liner 202 adjacent to the susceptor 205. The preheat ring 208 may allow uniform thermal transfer of the gas to the wafer. The present disclosure provides means for fixing the preheat ring 208 to the lower liner 202 and thus allowing an uniform spacing between the preheat ring 208 and the susceptor 205 during a hot epitaxial deposition process. Hereinafter, the provided means in the present disclosure may be described in details.

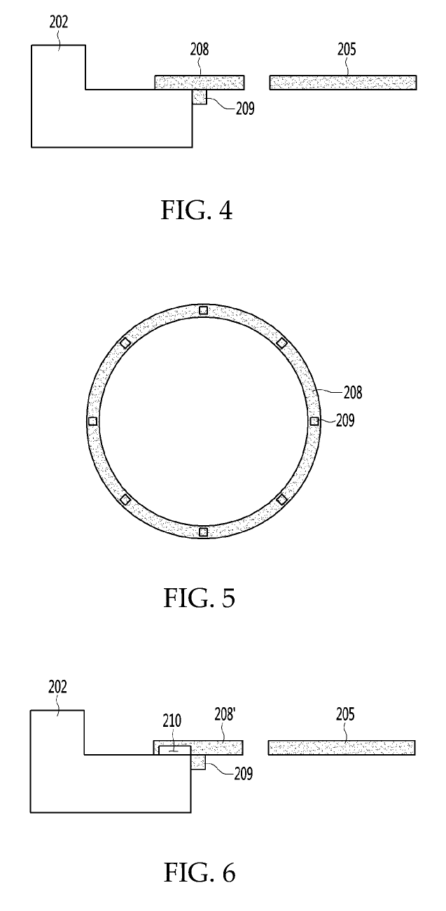

FIG. 4 illustrates a cross-sectional view of a preheat ring in an accordance with one embodiment of the present disclosure. In particular, FIG. 4 illustrates an enlarged cross-sectional view of a portion as shown in a dotted line in FIG. 3.

Referring to FIG. 4, a fixing member 209 may be disposed as a downward protrusion from the preheat ring 208. The fixing member 209 may contact with the lower liner 202. To be specific, an inner vertical circumferential face of the lower line 202 may contact an outer vertical circumferential face of the fixing member 209. In this way, the fixing member 209 may fix the preheat ring 208 to the lower liner 202.

The protrusion 209 may be implemented as a polygonal cross-sectional structure. Thus, each vertical face of the polygonal cross-sectional structure may suppress a horizontal deformation and/or displacement of the preheat ring 208. For example, the polygonal cross-sectional structure may be implemented as a hexagonal cross-sectional structure. In this connection, the vertical face of the polygonal cross-sectional structure 209 which contacts the lower liner 202 may be curved with the same curvature as that of an inner circumference of the lower liner 202.

The fixing member 209 may include a plurality of protrusions. Thus, a contact point between the fixing member 209 and lower liner 202 may include a plurality of contact points. The plurality of contact points may allow the preheat ring 208 to be secured to the lower liner 202 firmly and horizontally. This may suppress the deformation and/or displacement of the preheat ring, and, thus, particles creations.

FIG. 5 illustrate a bottom view of a preheat ring in accordance with one embodiment of the present disclosure.

Referring to FIG. 5, the fixing member 209 is disposed in a plural manner beneath the preheat ring 208 such each member has a contact face with the lower liner 202. For example, at least three fixing members 209 may be disposed in forms of respective protrusions to suppress a horizontal displacement and/or deformation of the preheat ring 208. In another embodiment, the fixing member 209 may be implemented as a ring structure to continuously contact the lower liner 202.

When the fixing member 209 is implemented as the plurality of protrusions, the protrusions may be arranged in a symmetrical manner from and along the preheat ring 208. In other words, two opposite protrusions may be arranged to be spaced from each other in a 180 degree angular distance. That is, an extension line between the opposite protrusions may encounter a center of an inner circumference of the preheat ring 208. In this way, the suppression of the displacement and/or deformation of the preheat ring 208 may be conducted in a symmetrical and uniform manner. Further, the preheat ring 208 may be fabricated with consideration of a margin for facilitating the seating of the ring 208 on the lower liner 202.

For an uniform suppression of the displacement and/or deformation of the preheat ring 208, the plurality of protrusions 209 may be arranged along the preheat ring 208 while being spaced from each other in a uniform distance. That is, the plurality of the fixing members 209 may be arranged repeatedly in an uniform distance around the susceptor 205. Although it may be preferable that the number of the fixing members 209 is small as possible as in order to decrease a contact area between the lower liner 209 and fixing member 209, the number of the fixing members 209, and the contact area thereof with the lower liner 209 may be selected based on a size of the preheat ring 208 and a correlation between the fixing member and the lower liner in terms of process conditions. In one embodiment of the present disclosure, an angular spacing between adjacent fixing members 209 may be 45 degree. Thus, a total number of the fixing members 209 may be 8.

Regarding a formation of the fixing member 209, the fixing member 209 may be formed in a monolithic manner with the preheat ring 208. This may be achieved by removing a lower portion of a preheat ring workpiece in a predetermined shape. In an alternative, the fixing member 209 may be attached/detached to/from the preheat ring 208. In this case, the fixing member 209 and preheat ring 208 may be made of the same material to have the same thermal expansion.

When using the epitaxial growth apparatus including the preheat ring with the fixing member in accordance with the embodiment, a peeled off SiC coating from the susceptor due to the friction between the preheat ring and susceptor may be suppressed, leading to a reduction of in-chamber contaminations due to the peeled off SiC coating. Further, particles generations due to the friction between the preheat ring and lower liner may be suppressed, leading to a suppress of contaminations on the resulting grown epitaxial wafer.

FIG. 6 illustrates a cross-sectional view of a preheat ring in accordance with another embodiment of the present disclosure. Referring to FIG. 6, the preheat ring 208′ may have a groove 210 defined therein. The groove may have a predetermined depth, and may contact the lower liner 209. The groove 210 contacts a top face of the lower liner 202. The groove may be divided into a plurality of sub-grooves arranged repeatedly and circumferentially in a uniform distance along the preheat ring 208′. The groove may act to reduce a contact area between the preheat ring 208′ and lower liner 202. In an alternative, the groove 210 may continuously and circumferentially extend along the preheat ring. In this case, the groove extends in a ring shape along the preheat ring.

In this way, only a substantially outermost portion of the preheat ring 208′ may contact the lower liner 202. This may reduce particles creations due to the friction between the liner and ring resulting from thermal expansion during the epitaxial process.

Further, the fixing member 209 disposed beneath the preheat ring 208′ may be formed of a structure having a plurality of side faces as in the embodiment as shown in FIG. 4. The fixing member 209 may include a plurality of protrusions spaced from each other and arranged along the preheat ring 208′ in order to reduce a friction between the lower liner 202 and ring 208′. The number of the protrusions, the spacing between adjacent protrusions and/or a contact area between the lower liner 202 and protrusions may vary depending on a size of the preheat ring 208′, process conditions, etc.

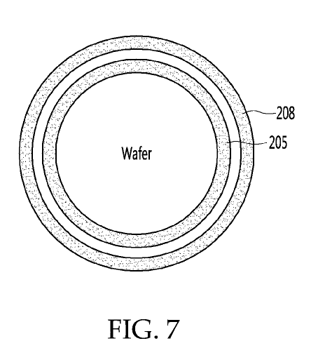

FIG. 7 illustrates a top view of a preheat ring and susceptor in accordance with the present disclosure. Referring to FIG. 7, the epitaxial growth apparatus of the present disclosure may enable uniform gas flow along and on the wafer during rotation of the susceptor because the susceptor 205 and preheat ring 208 are spaced from each other in a constant distance around the susceptor while being coplanar with each other.

Further, the preheat ring 208 and susceptor 205 may be suppressed from contacting each other, and, thus, the susceptor may be prevented from being peeled off and, in turn, from forming metal precipitations. Thus, metal contaminations may be suppressed. This may improve a yield of the resulting epitaxial wafer.

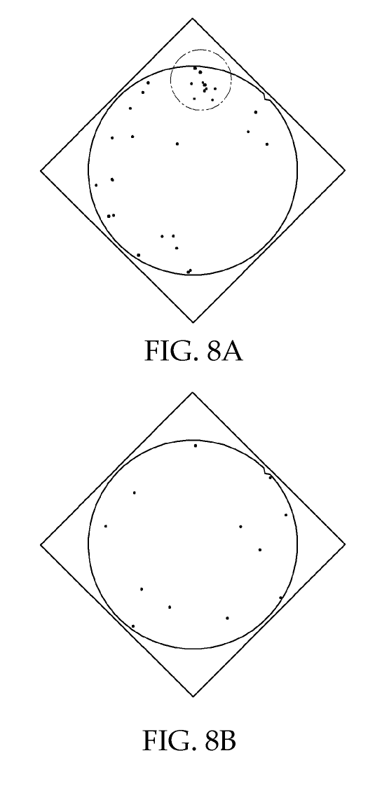

FIG. 8 illustrates a comparison in LLS (Localized Light Scatters) defects between resulting wafers respectively in cases of presence and absence of a contact between a susceptor and a preheat ring during a wafer epitaxial process.

FIG. 8A illustrates LLS defects on the wafer surface when there is a contact between the preheat ring and susceptor. In particular, multiple LLSs are formed in a region defined by a dotted line to exhibit patterned LLSs of a 0.2 μm size.

FIG. 8B illustrates LLS defects on the wafer surface when there is no contact between the preheat ring and susceptor, that is, when there is kept a uniform spacing therebetween. This may be achieved using the preheat rings of the first and/or second embodiments. As shown in the figure, patterned LLSs do not appear.

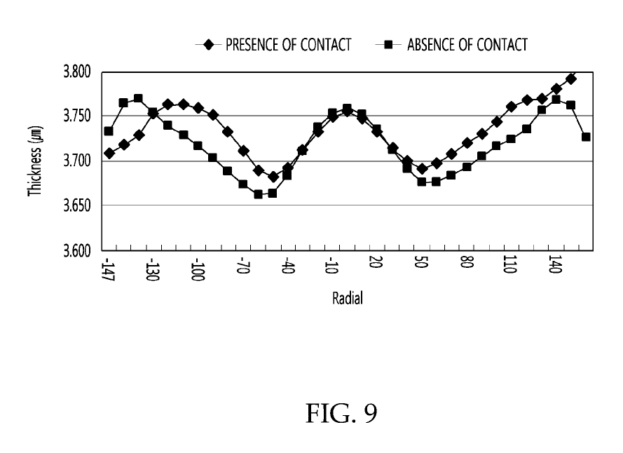

FIG. 9 illustrates epitaxial layer thickness variations over a radial direction, respectively for resulting wafers respectively in cases of presence and absence of a contact between a susceptor and a preheat ring during a wafer epitaxial process.

When there is no contact between the preheat ring and susceptor, that is, when there is kept a uniform spacing therebetween, a uniform gas flow along and on the wafer surface may be enabled to result in a symmetrical variation of the epitaxial layer thickness deposited on the wafer over the radial direction. To the contrary, when there is a contact between the preheat ring and susceptor, that is, when there is not kept a uniform spacing therebetween, a non-uniform gas flow along and on the wafer surface may occur to result in an asymmetrical variation of the epitaxial layer thickness deposited on the wafer over the radial direction. Especially, the asymmetrical variation is remarkable in an edge of the wafer. This may lead to poor smoothness of the resulting wafer, and, thus, a poor yield of a semiconductor device.

The epitaxial growth apparatus of the present disclosure includes the fixing member configured to fix the preheat ring to the lower liner, and, thus, to suppress the horizontal deformation and/or displacement of the preheat ring. This may lead to the uniform gas flow rate on and along wafer surface, and, hence, the symmetrical variation of the epitaxial layer thickness. This may improve better smoothness of the resulting wafer, and, thus, a better yield of a semiconductor device.

The above description is not to be taken in a limiting sense, but is made merely for the purpose of describing the general principles of exemplary embodiments, and many additional embodiments of this disclosure are possible. It is understood that no limitation of the scope of the disclosure is thereby intended. The scope of the disclosure should be determined with reference to the Claims. Reference throughout this specification to “one embodiment,” “an embodiment,” or similar language means that a particular feature, structure, or characteristic that is described in connection with the embodiment is included in at least one embodiment of the present disclosure. Thus, appearances of the phrases “in one embodiment,” “in an embodiment,” and similar language throughout this specification may, but do not necessarily, all refer to the same embodiment.

What is claimed is:

1. An epitaxial wafer growth apparatus for growing an epitaxial layer on a wafer using a process gas flow, the apparatus comprising:
a reaction chamber in which the process gas flow occurs;
upper and lower liners, each liner surrounding a side face of the reaction chamber;
a susceptor concentrically disposed in and with the reaction chamber, the susceptor configured to support the wafer thereon;
a preheat ring seated on a top face of the lower liner, the preheat ring being coplanar with the susceptor, and the preheat ring being spaced from the the susceptor; and
at least one protrusion extending downwards from the preheat ring, wherein the protrusion has a circumferential contact face with a circumferential side face of the lower liner, wherein the protrusion is configured to fix the preheat ring to the lower liner to keep a uniform spacing between the preheat ring and susceptor along the preheat ring.

2. The apparatus of claim 1, wherein the protrusion continuously extends along a circumference of the lower liner to form a ring shape.

3. The apparatus of claim 1, wherein the at least one protrusion includes at least three protrusions arranged along the preheat ring.

4. The apparatus of claim 3, wherein the at least three protrusions include eight protrusions, wherein adjacent ones of the eight protrusions are spaced from each other in a 45 degree angular distance.

5. The apparatus of claim 1, wherein the at least one protrusion includes a plurality of protrusions arranged along the preheat ring, wherein the plurality of protrusions are arranged symmetrically around the susceptor.

6. The apparatus of claim 1, wherein the at least one protrusion includes a plurality of protrusions arranged along the preheat ring, wherein the plurality of protrusions are arranged repeatedly in an uniform distance around the susceptor.

7. The apparatus of claim 1, wherein the circumferential contact face has the same curvature as that of the circumferential side face of the lower liner.

8. The apparatus of claim 1, wherein the protrusion is monolithic with the preheat ring.

9. The apparatus of claim 1, wherein the protrusion is configured to be attached/detached from/to the preheat ring.

10. The apparatus of claim 1, wherein the preheat ring has a groove defined therein, where the groove contacts the lower liner.

11. The apparatus of claim 10, wherein the groove continuously and circumferentially extends along the preheat ring.

12. The apparatus of claim 11, wherein the groove extends in a ring shape along the preheat ring.

13. The apparatus of claim 10, wherein the groove are divided into a plurality of sub-grooves arranged repeatedly and circumferentially in a uniform distance along the preheat ring.
